(19) United States
(12) Patent Application Publication
(10) Pub. No.: US 2013/0242493 A1
(43) Pub. Date: Sep. 19, 2013

(54) LOW COST INTERPOSER FABRICATED WITH ADDITIVE PROCESSES

(71) Applicants: Ravindra V. Shenoy, Dublin, CA (US); David William Burns, Dublin, CA (US); Evgeni P. Gousev, Saratoga, CA (US)

(72) Inventors: Ravindra V. Shenoy, Dublin, CA (US); David William Burns, Dublin, CA (US); Evgeni P. Gousev, Saratoga, CA (US)

(73) Assignee: QUALCOMM MEMS TECHNOLOGIES, INC., San Diego, CA (US)

(21) Appl. No.: 13/418,834

(22) Filed: Mar. 13, 2012

(51) Int. Cl. G06F 1/18; H05K 3/00; H05K 7/06

(52) U.S. Cl. 361/679.21; 361/748; 29/829

(57) ABSTRACT

This disclosure provides systems, methods and apparatus for interposers in compact three-dimensional (3-D) device packages. In one aspect, one or more methods of fabricating an interposer using an additive process are provided. The additive process can involve depositing flowable dielectric material around a plurality of metal interconnect posts after forming the plurality of metal interconnect posts on a carrier substrate. In another aspect, an interposer including through-glass vias and one or more passive devices is provided.

### TECHNICAL FIELD

This disclosure relates generally to three-dimensional (3-D) device packaging and more particularly to electrically conductive interconnects for 3-D device packages.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Device packaging in electromechanical systems can protect the functional units of the system from the environment, provide mechanical support for the system components, and provide a high-density interface for stacked electrical interconnections between devices and substrates.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of forming an interposer. The method can include forming a sacrificial layer on a carrier substrate and forming a plurality of interconnect posts on the sacrificial layer. The plurality of interconnected posts can be oriented substantially perpendicular to the carrier substrate. One or more flowable dielectric layers can be deposited and solidified to cover the sacrificial layer and the plurality of interconnect posts. The solidified dielectric material can be planarized to expose the plurality of interconnect posts and to form an interposer layer releasably attached to the carrier substrate via the sacrificial layer. In some implementations, the one or more flowable dielectric layers can include one or more spin-on dielectrics or one or more epoxy layers. In some implementations, forming a plurality of interconnect posts can include plating metal posts in a patterned photoresist layer.

The method can further include forming one or one more passive components on the solidified dielectric material. Examples of passive components include resistors, capacitors, and inductors. In some implementations, one or more passive components can be formed after planarizing the solidified dielectric material. In some implementations, one or more passive components can be formed after forming the sacrificial layer on the carrier substrate and before depositing any flowable dielectric layers. The method can further include plating the plurality of interconnect posts with solderable material. In some implementations, the method can further include forming one or more routing layers on the solidified dielectric material.

Another innovative aspect of this disclosure can be implemented in an interposer. The interposer can include an additive glass interposer layer and one or more metal interconnect posts extending through the glass interposer layer. In some implementations, a routing layer including electrically conductive routing lines can be connected to the one or more metal interconnect posts. The density of the routing lines can greater than the density of the interconnect posts. Examples of metals in a metal interconnect post can include nickel, nickel alloy, and copper. In some implementations, the metal interconnect posts can have height to width aspect ratios of greater than about 5:1. Example heights of the metal interconnect posts range from about 10 microns to about 100 microns, and in some cases as much as about 500 microns. Example widths of the metal interconnect posts range from about 5 microns to about 100 microns. Example thicknesses of the glass interposer layer can range from about 10 microns to about 500 microns. In some implementations, the interposer can include one or more passive components on the glass interposer layer. In some implementations, a metal interconnect post can include an interconnect cap that protrudes from the spin-on glass substrate. An interconnect cap can include a solderable material in some implementations.

Another innovative aspect of this disclosure can be implemented in a method of forming an interposer that includes using an additive process to fabricate an additive glass interposer layer on a carrier substrate and integrating one or more passive components within the interposer layer during the additive process. Examples of passive components include resistors, capacitors and inductors. In some implementations, using the additive process includes depositing flowable dielectric material around a plurality of metal interconnect posts and the carrier substrate after forming the plurality of metal interconnect posts on the carrier substrate.

Another innovative aspect of this disclosure can be implemented in an apparatus. The apparatus can include a packaging substrate, an interposer layer in electrical communication with the packaging substrate, and one or more dies positioned over the interposer layer. The interposer layer can include a solidified dielectric material, one or more metal interconnect posts extending through the solidified dielectric material, and a routing layer including electrically conductive routing lines connected to the one or more metal interconnect posts. In some implementations, the density of electrical connections from the routing layer to the one or more dies is greater than the density of electrical connections from the interposer layer to the packaging substrate. In some implementations, the solidified dielectric material can include spin-on-glass or epoxy. Examples of dies include at least one of memory, logic, radio frequency, application specific integrated circuit, and MEMS chips. In some implementations, the one or more dies can include stacked dies. The apparatus can further include one or more passive components within the interposer layer. Examples of passive components include resistors, capacitors and inductors.

Another innovative aspect of this disclosure can be implemented in an apparatus including an interposer formed by a process including forming a plurality of interconnect posts on a sacrificial layer, the sacrificial layer formed on a carrier substrate; depositing and solidifying one or more flowable dielectric layers around the interconnect posts; planarizing the solidified dielectric material to expose the interconnect posts; and releasing the interposer from the carrier substrate by sacrificially etching the sacrificial layer.

The apparatus can further include one or more routing layers on an upper side or a lower side of the interposer. At least one passive component can be formed on an upper side or a lower side of the interposer. In some implementations, at least one interconnect post provides strain relief when the interposer is connected between a packaging substrate and an integrated circuit chip. In some implementations, at least one interconnect post allows heat transfer between an integrated circuit chip and a packaging substrate, the interposer connected between the packaging substrate and the integrated circuit chip. The apparatus can further include one or more of an integrated circuit chip and a packaging substrate attached to the interposer. In some implementations, the interposer provides stress isolation between a packaging substrate and an integrated circuit chip attached to the interposer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a flow diagram illustrating a manufacturing process for forming an interposer.

FIG. 10 shows an example of a flow diagram illustrating a manufacturing process for forming an interposer.

FIGS. 11A-11G show examples of cross-sectional schematic illustrations of various stages in a method of manufacturing an interposer layer.

FIGS. 12A-12C show examples of cross-sectional schematic illustrations of varying implementations of interposers with one or more routing layers.

FIG. 13 shows an example of a cross-sectional schematic illustration of stacked dies on an interposer.

FIGS. 14A-14D show examples of cross-sectional schematic illustrations of various stages in a method of forming an interposer.

FIGS. 15A and 15B show examples of cross-sectional schematic illustrations of an interposer positioned between an integrated circuit chip and a packaging substrate.

FIGS. 16A and 16B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein relate to 3-D device packaging and interposer technology. An interposer generally serves as an intermediate layer that can be used for direct electrical interconnection between one device or substrate and a second device or substrate with the interposer positioned in between. For example, an interposer may have a pad configuration on one side that can be aligned with corresponding pads on a first device, and a different pad configuration on a second side that corresponds to pads on a second device. The interposer can contain electrical traces that allow interconnecting pads to be aligned and mated to devices on opposite sides. In some implementations, the interposer includes an interposer layer that has electrically conductive interconnects (vias) extending through the layer. For example, in some implementations, the interposer layer can be a through-glass via layer. For example, in some implementations, the interposer layer can be an additive glass interposer layer. In some implementations, the interposers can further include one or more routing or redistribution layers. In some implementations, the interposer may include a ground plane and/or a power plane. In some implementations, one or more passive components can be integrated within the interposer. In some implementations, one or more devices may be attached to each side of the interposer.

Some implementations described herein relate to additive processes to fabricate interposers. An additive process can involve depositing flowable dielectric material over a plurality of metal interconnect posts and solidifying the flowable dielectric material. In some implementations, the process can further include forming the plurality of metal interconnect posts on a carrier substrate prior to depositing the flowable dielectric material. For example, the flowable dielectric material may be deposited by spinning, dispensing, extruding, injecting, casting or otherwise disposing the dielectric material around, and in some cases, over the interconnect posts. The interconnect posts may be formed, for example, directly on the carrier substrate or on a sacrificial layer disposed on the carrier substrate. Examples of flowable dielectric material include spin-on dielectric and epoxy materials. The process can further include planarizing the solidified dielectric material to form an interposer layer including through-layer interconnects. In some implementations, one or more passive components can be formed prior to or after forming the solidified dielectric material. In some implementations, one or more routing or redistribution layers can be formed prior to or after forming the solidified dielectric material.

Some implementations relate to additive glass interposer layers. An additive glass interposer layer is any interposer layer formed by solidifying a flowable dielectric material such as a dispensable glass or epoxy around one or more interconnect posts of the interposer layer.

Particular implementations of the subject matter described in this disclosure can be implemented to realize one or more of the following potential advantages. Forming an interposer layer using an additive process can reduce the cost of fabrication in comparison to subtractive processes that require multiple patterning and deposition operations. Use of a flowable dielectric material around electroplated posts allows relatively thin interposers to be formed. The posts may be formed with a relatively high density. Patterned photoresist materials may be used to form the electroplated posts, which can then be removed and replaced with a stronger material having a high dielectric strength. One or more routing layers separated by thin dielectric layers may be formed prior to or after formation of the posts. Passive components can also be integrated in a cost-efficient manner within the interposer by using an additive process. Additive processes are also scalable to large panel or continuous roll substrates that can further reduce cost.

Some implementations described herein relate to 3-D device packaging, including packaging of EMS or MEMS devices. An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

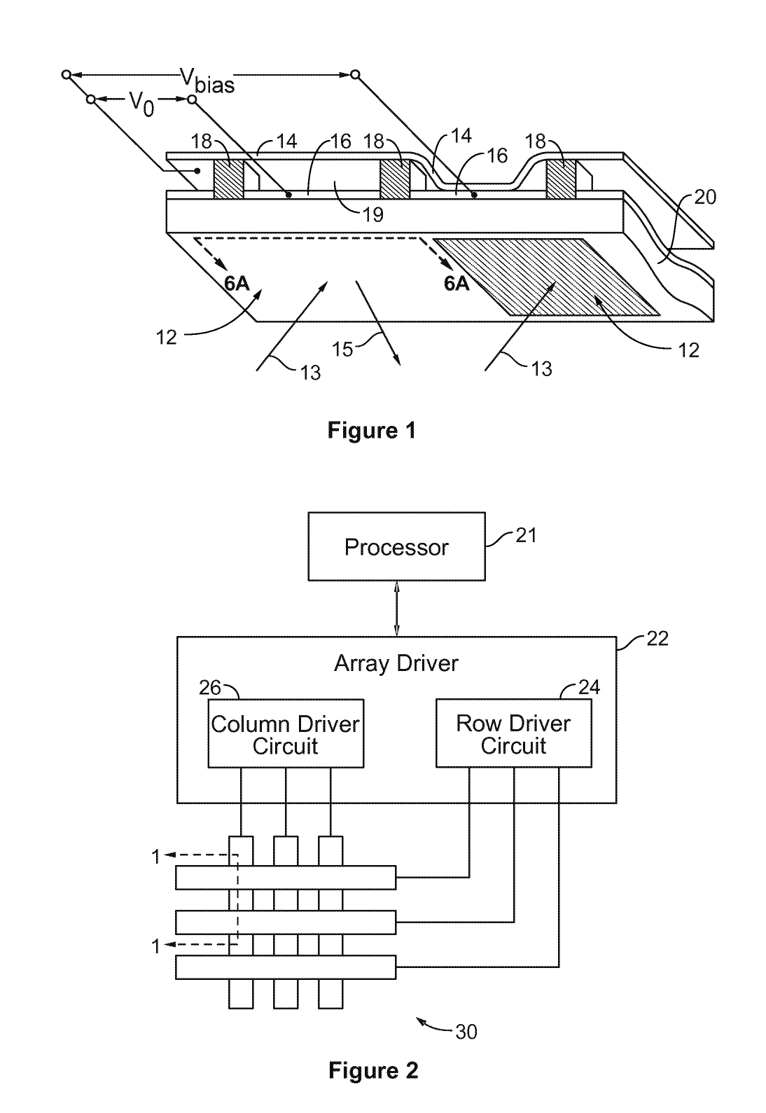

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

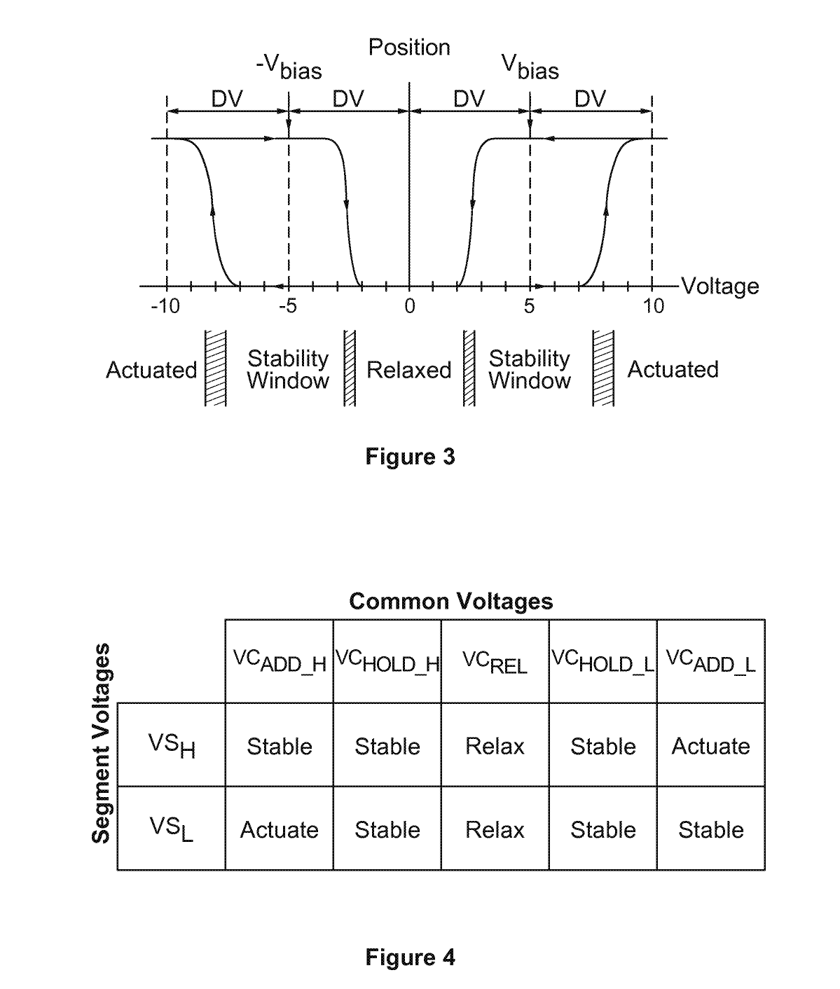

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

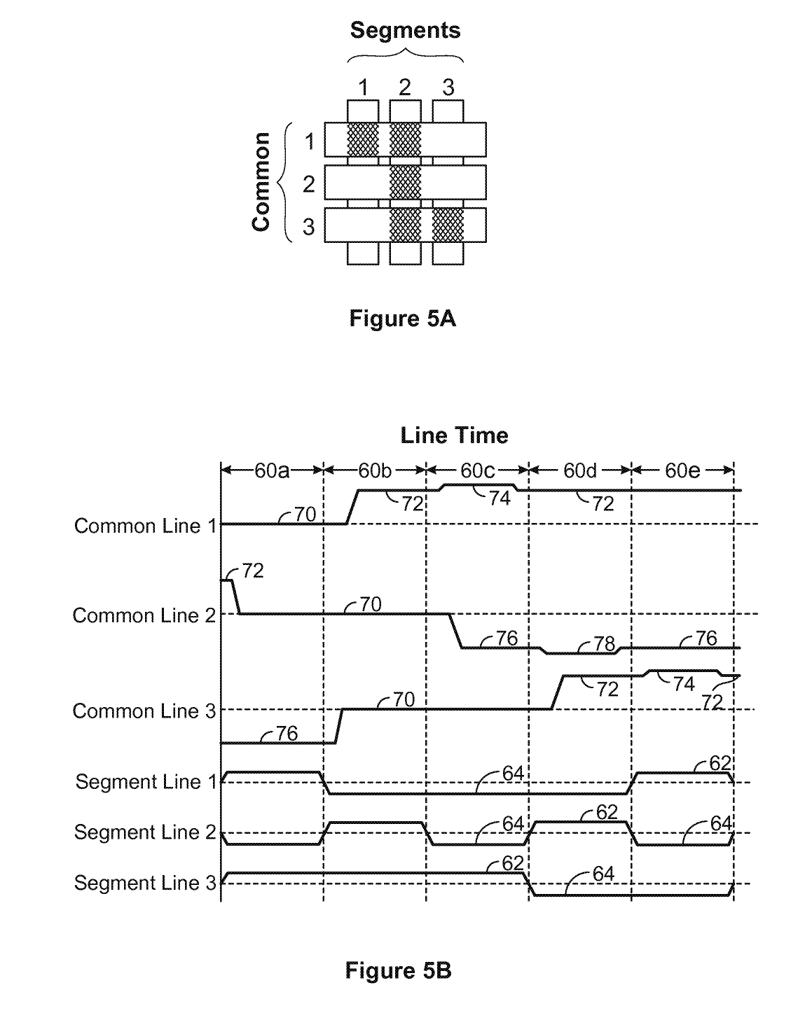

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

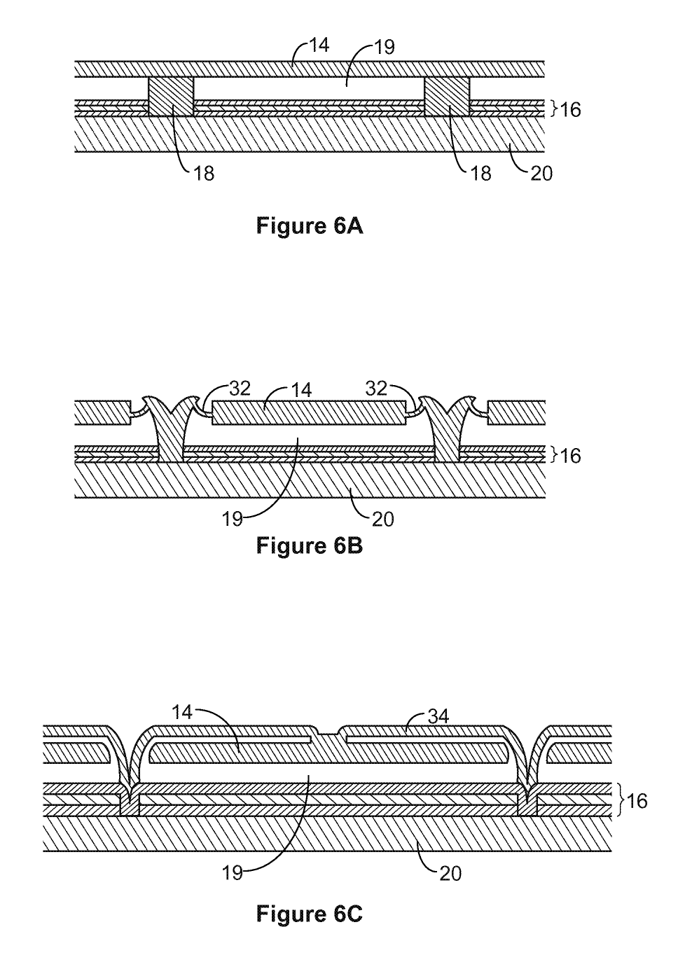

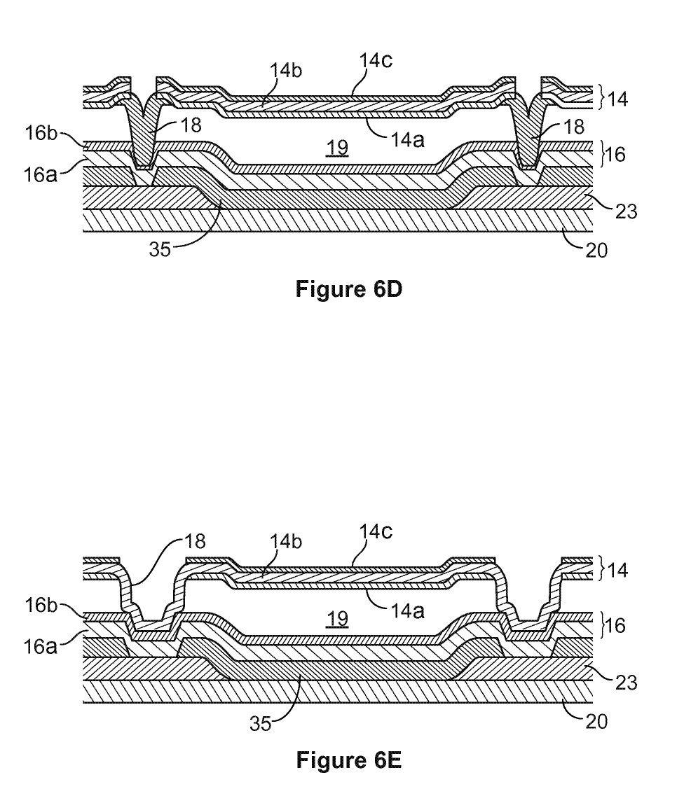

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

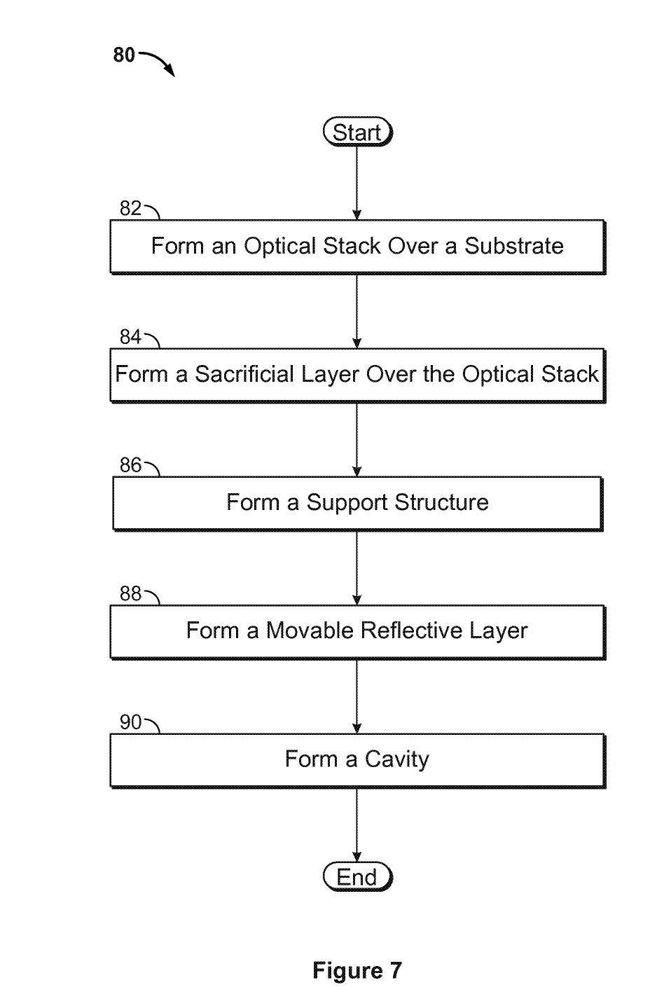

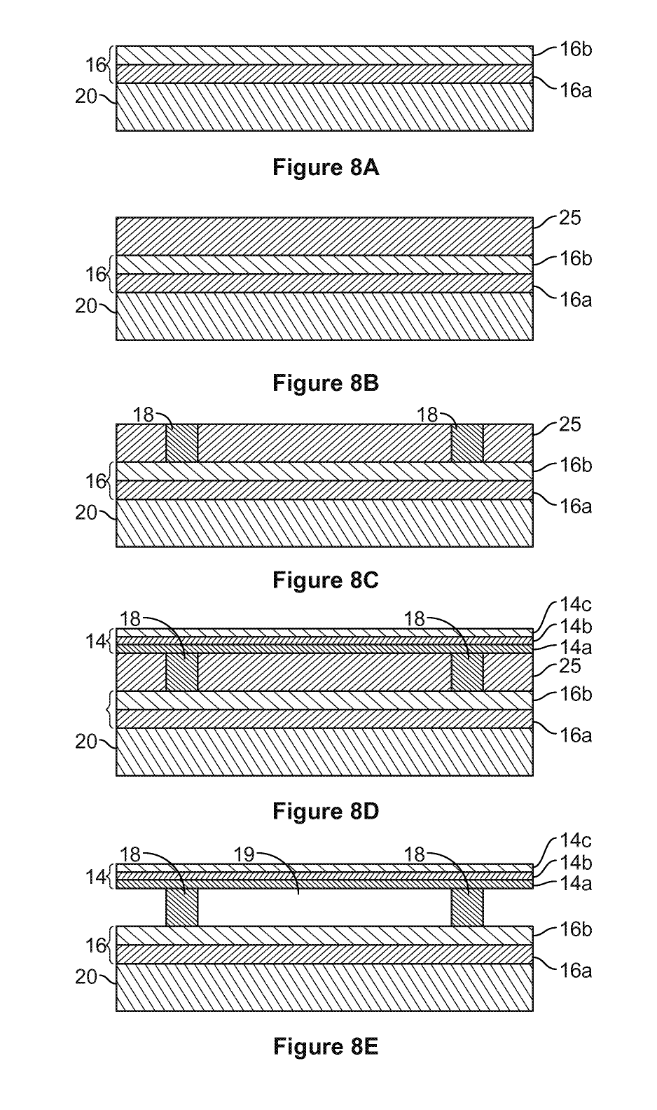

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Implementations described herein relate to interposers and interposers for use in compact three-dimensional (3-D) packages. In some implementations, methods of manufacturing an interposer are described. An interposer is an intermediate layer that can be used for interconnection routing or as a ground or power plane. Interposers can be incorporated within 3-D device packages, such as packages for memory, logic, EMS, MEMS, and other chip devices. In a 3-D structure, electronic components such as semiconductor chips, EMS devices, and the like can be provided in a stacked structure. Interposers can connect components in different layers of a 3-D stacked structure.

In some implementations, the interposers described herein include glass or epoxy substrates having through-substrate interconnects (vias). For example, a through-glass via interposer is an interposer including electrically conductive vias that extend through a glass interposer layer and that can provide electrical interconnection between components on both sides of the layer. While portions of the discussion below refer to through-glass via interposers, it is understood that dielectric substrates other than glass may be used, such as epoxy substrates.

Through-glass via interposers may be used to provide electrical interconnections and mechanical support to electrically connect components in different layers in a stacked structure. In one implementation, two or more dies having integrated circuits may be stacked such that through-glass vias electrically connect the integrated circuits. Through-glass via interposers can provide high wiring density interconnection, reduce coefficient of thermal expansion (CTE) mismatch to the connected dies, and improve electrical performance due to shorter interconnection from the dies to a packaging substrate.

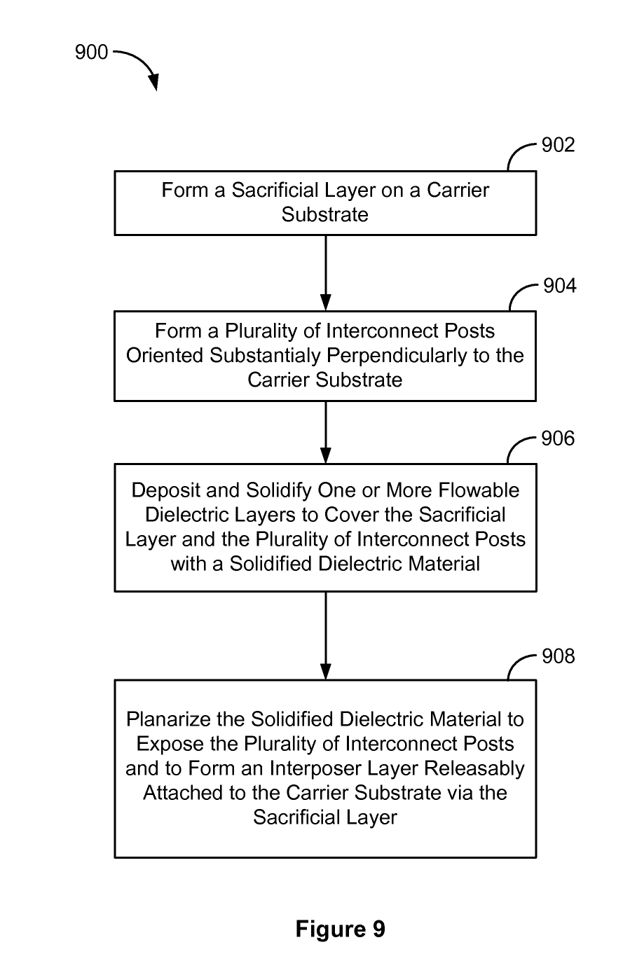

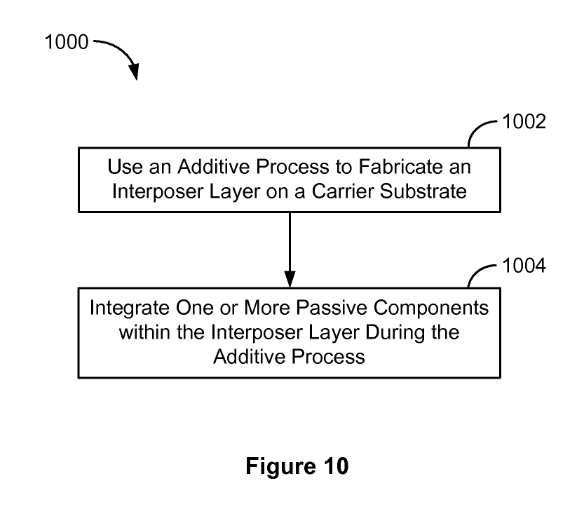

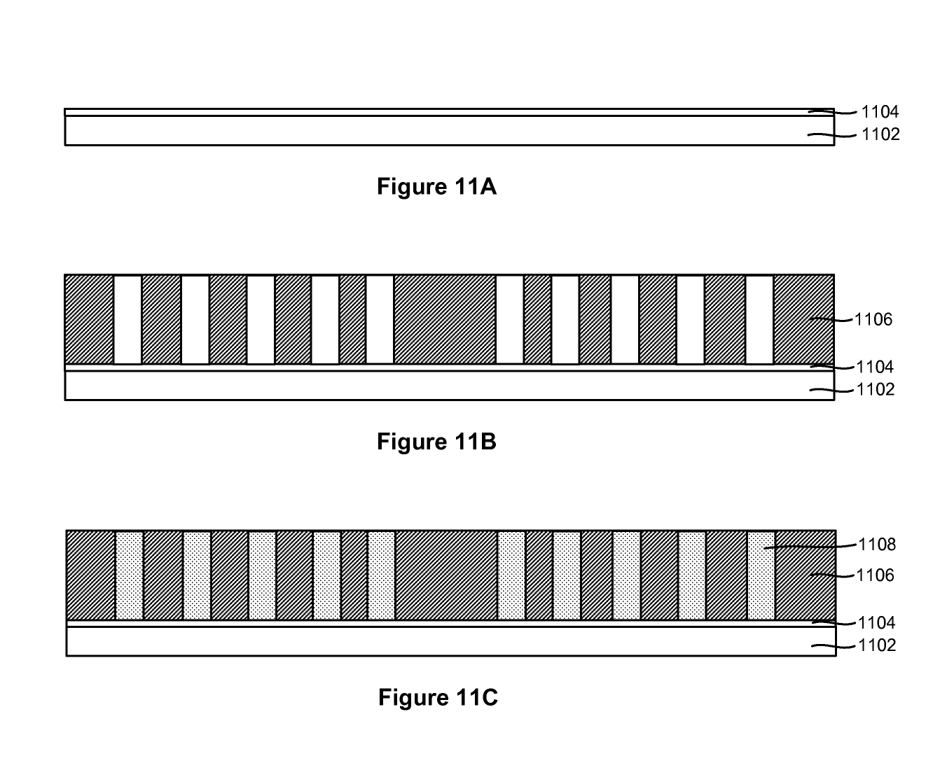

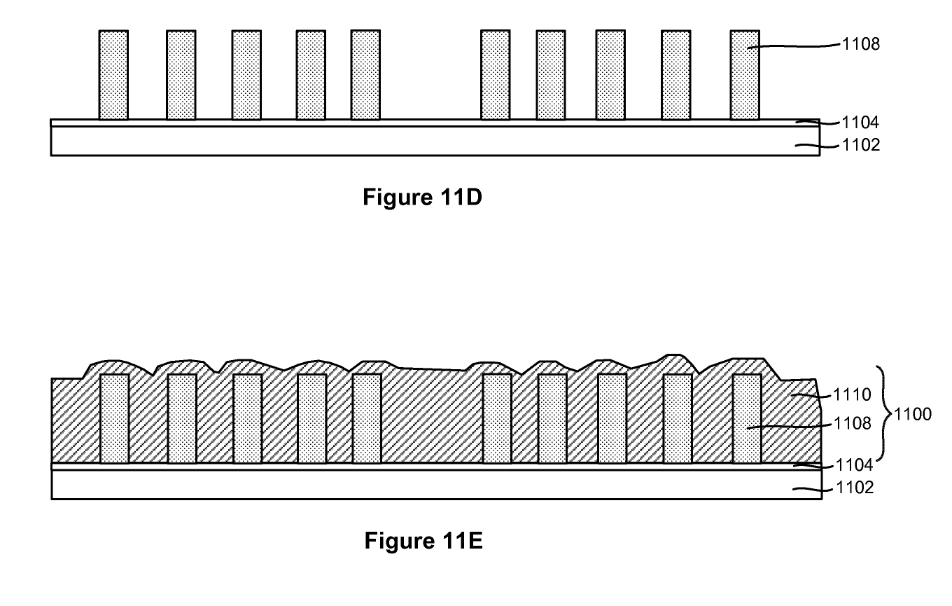

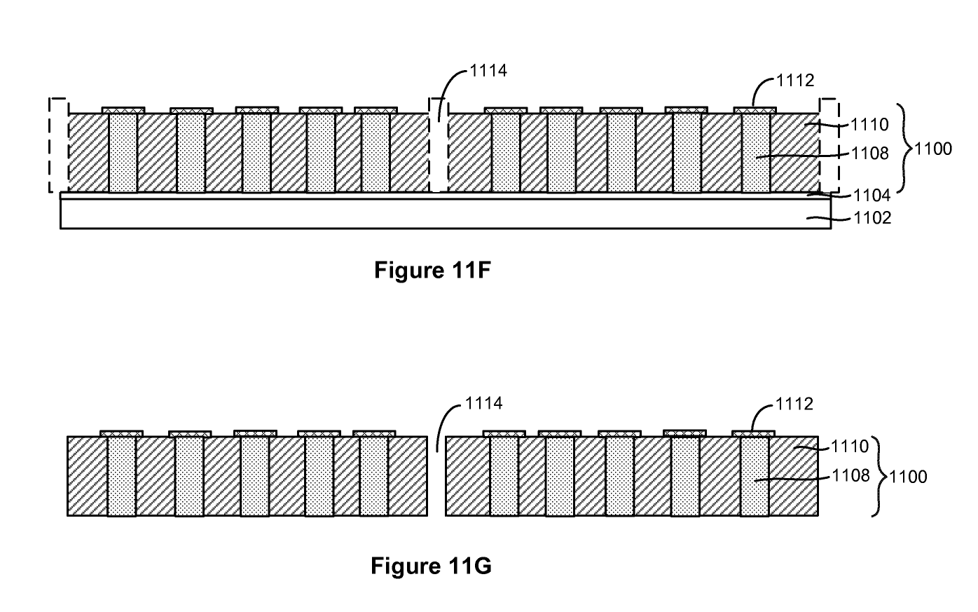

In some implementations, through-substrate via interposers, including through-glass and through-epoxy via interposers, can be formed using an additive process. An overview of an additive process according to some implementations is given in FIG. 9, with examples of specific implementations described further below with reference to FIGS. 10-11G.

FIG. 9 shows an example of a flow diagram illustrating a manufacturing process for forming an interposer. The process 900 begins at block 902 where a sacrificial layer is formed on a carrier substrate. The carrier substrate may be transparent or non-transparent. Examples of carrier substrate materials can include glass, plastic, and silicon. The sacrificial layer can be any material that can be selectively removed from the interposer layer. Examples include sputtered Cu, sputtered Al, and laser-cleavable polymers. Further examples of carrier substrates and sacrificial materials are described below with reference to FIG. 11A.

The process 900 continues at block 904 where a plurality of interconnect posts are formed that are oriented substantially perpendicularly to the carrier substrate. Forming the plurality of interconnect posts can include plating a plurality of metal posts in a patterned photoresist layer. In some implementations, the metal posts can be electrically conductive vias.

The process 900 continues at block 906 where one or more flowable dielectric layers are deposited and cured to cover the sacrificial layer and the plurality of interconnect posts with a solidified dielectric material. In some implementations, the one or more flowable dielectric layers can include one or more spin-on-glass layers. In some implementations, the one or more flowable dielectric layers can include one or more epoxy layers.

The process 900 continues at block 908 where the solidified dielectric material is planarized to expose the plurality of interconnect posts and to form an interposer layer releasably attached to the carrier substrate via the sacrificial layer. In some implementations, the process 900 can continue with releasing the interposer layer from the carrier substrate (not shown).

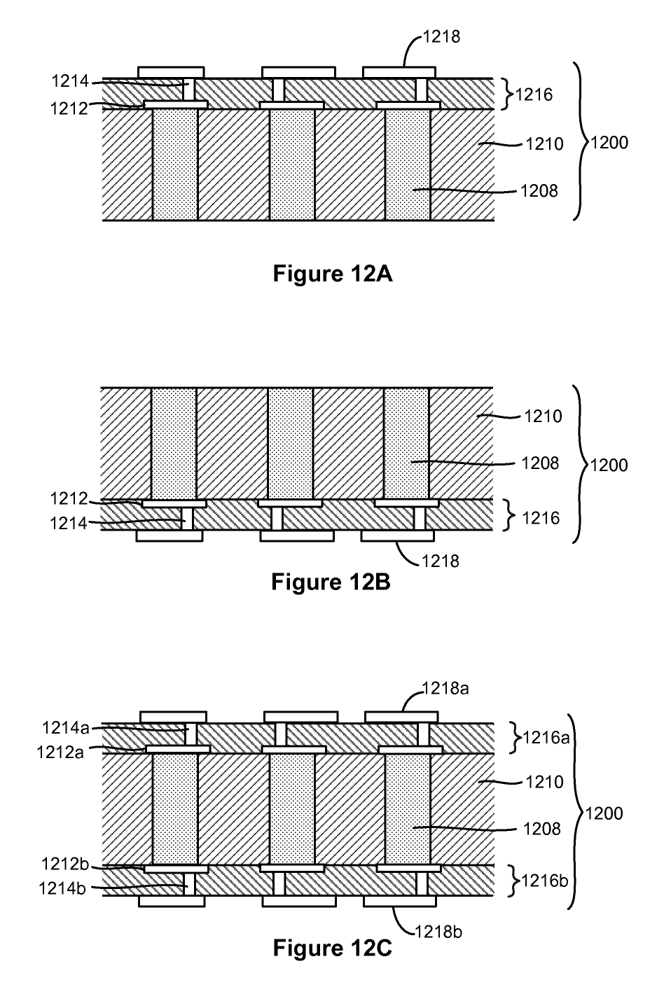

Additional operations may also be present in the process 900. For example, in some implementations, the process 900 can also include plating the plurality of interconnect posts with solderable material. In another example, in some implementations, the process 900 can include forming one or more routing layers on the solidified dielectric material. Interposers including routing layers are described below with reference to FIGS. 12A-12C. In yet another example, the process 900 can include forming one or more passive components on the solidified dielectric material, as described below with reference to FIG. 10.

FIG. 10 shows an example of a flow diagram illustrating a manufacturing process for forming an interposer. The process 1000 begins at block 1002 where an additive process is used to fabricate an interposer layer on a carrier substrate. In some implementations, the additive process includes depositing flowable dielectric material over a plurality of metal interconnect posts after forming the plurality of metal interconnect posts on the carrier substrate.

The process 1000 continues at block 1004 where one or more passive components are integrated within the interposer layer during the additive process. In some implementations, the one or more passive components include at least one of a resistor, a capacitor or an inductor. In some implementations, block 1004 can include forming one or more passive components on a surface of the interposer layer fabricated in block 1002. For example, a passive component can be vacuum deposited on a dielectric surface or a metal interconnect of the interposer layer. In some implementations, block 1004 can include forming one or more passive components on a sacrificial layer, prior to depositing and curing a flowable dielectric material over the passive components. In some implementations, block 1004 can include forming one or more passive components in between deposition of layers of a flowable dielectric material. Passive components can be formed by thin film deposition processes including CVD, atomic layer deposition (ALD), PVD or other vapor deposition technique, electrodeposition, or by ink-jet deposition.

FIGS. 11A-11G show examples of cross-sectional schematic illustrations of various stages in a method of manufacturing an interposer layer. FIG. 11A is a cross-sectional illustration of a sacrificial layer 1104 covering a carrier substrate 1102. In subsequent operations described below, a through-substrate via interposer layer can be formed on the carrier substrate 1102.

The carrier substrate 1102 can be glass, plastic, silicon, or other appropriate material. In some implementations, the carrier substrate 1102 can be a large panel or glass plate having an area on the order of about four square meters or more. In some implementations, the carrier substrate 1102 can be provided in a roll, such as a flexible polymer or other flexible material. For example, the carrier substrate 1102 can be provided in a continuous roll of material as part of a roll-to-roll process. Fabrication of the interposer layer on such implementations of the carrier substrate 1102 can facilitate large format batch processing.

In some implementations, the carrier substrate 1102 can have a thickness of about 50 microns to about 1000 microns. In some implementations, if the carrier substrate 1102 is a large panel, the thickness can be about 300 microns to about 1000 microns. In other implementations, if the carrier substrate 1102 is a roll, the thickness can be about 50 microns to about 300 microns.

Other substrate materials and thicknesses can be used for the carrier substrate 1102 on which a sacrificial material can be formed. For example, in some implementations, the carrier substrate 1102 can be any material that is inert, has good planarity, is thermally stable at subsequent processing temperatures, and has a similar CTE match with a dielectric material such as spin-on glass. In some implementations, the carrier substrate can be thermally stable at temperatures of at least about 300°, and in some cases, at least about 400° C. The carrier substrate can be substantially planar or can include topographical features. For example, a carrier substrate can include recesses that correspond to the positions of subsequently formed interconnect posts to facilitate the formation of interconnect posts with protrusions.

In some implementations, the sacrificial layer 1104 coats the surface of the carrier substrate 1102 on which the through-substrate interposer layer is formed upon, such that removal of the sacrificial layer 1104 releases the carrier substrate 1102 from the interposer layer. The sacrificial layer 1104 can be any material that can be selectively removed without damaging the interposer layer. Examples of sacrificial materials can include metals, semiconductors, and acrylics. For example, the sacrificial material can be a material removable by a wet or dry etching process such as Cu, Mo, MoCr, Al, and amorphous Si. In another example, the sacrificial material can be a material removable by exposure to radiation or thermal treatment such as a UV-removable acrylic. In some implementations, the sacrificial material can be formed from a combination of different sacrificial materials. For example, a first sacrificial material can be used to coat a surface of the carrier substrate 1102 with a second sacrificial material used to form topological features according to the desired implementation. The surface on which the sacrificial layer 1104 is deposited can be planar or include raised or recessed features according to the desired implementation. The sacrificial layer 1104 is generally conformal to the underlying carrier substrate 1102.

In some implementations, the sacrificial layer 1104 can serve as a seed layer for subsequent interconnect plating. For example, Cu can be both a seed layer and a sacrificial layer. Other examples can include Al, Cr, gold (Au), niobium (Nb), tantalum (Ta), nickel (Ni), tungsten (W), titanium (Ti), and silver (Ag). The sacrificial layer 1104 can be deposited by sputter deposition, though other conformal deposition processes, including ALD, evaporation and other CVD or PVD processes may be used. Example seed layer thicknesses range from about 800 Å to about 10,000 Å, for example from about 1000 Å to about 5000 Å.

In some other implementations, a seed layer (not shown) can be formed on the sacrificial layer 1104. As examples, a metal seed layer (for example, a Cu seed layer) can be formed on a sacrificial layer of sputtered Al, or a metal seed layer can be formed on a sacrificial layer of a laser-cleavable polymer. Also in some implementations, one or more passive components (not shown) can be fabricated on the sacrificial layer 1104 prior to photoresist deposition.

FIG. 11B shows a cross-sectional illustration of a photoresist layer 1106 formed on the sacrificial layer 1104 and patterned to define interconnect post placement. The photoresist layer 1106 can be patterned by techniques including masked exposure to radiation and chemical development. The photoresist layer 1106 can include any suitable photoresist that can be applied and patterned at a desired thickness, can be stripped easily, and can withstand thermal cycles of about 150° C. or more. Examples of suitable photoresists can include AZ®4562 and AZ®9260 available from AZ Electronics Materials in Branchburg, N.J., Dupont WBR 2000™ Series photoresists, and SU-8 and KMPR photoresists from MicroChem in Newton, Mass.

The photoresist layer 1106 can have a thickness according to the desired thickness of the interposer layer. The thickness of the photoresist layer 1106 may be about 10% to about 30% greater than the desired interposer layer thickness to accommodate non-uniformity in plating and subsequent planarization. For example, to achieve an interposer thickness of between about 25 microns and about 100 microns, the photoresist thickness can be about 30 microns to about 125 microns.

FIG. 11C shows a cross-sectional illustration of the plated interconnect posts 1108 in the patterned photoresist layer 1106. Any appropriate metal material may be used for the interconnect posts 1108. Examples of interconnect metals may include but are not limited to plated Ni, Ni alloys, Cu, Cu alloys, Au, Au alloys, Al, Al alloys, Ti, Ti alloys, W, W alloys, palladium (Pd), Pd alloys, tin (Sn), Sn alloys, and combinations thereof. In some other implementations, the interconnect posts 1108 can include non-metal conductive materials such as polysilicon in addition to or instead of a metal. In some implementations, the sacrificial layer 1104 has a different metallization than that used for the metal interconnect posts 1108. This is to preserve etch selectivity of the sacrificial layer 1104 with respect to the interconnect posts 1108. For example, a Ni or Ni alloy may be plated on a sputtered Cu layer that functions as sacrificial layer as well as a seed layer. In another example, a Cu or Ni alloy may be plated on a sputtered Cu seed layer, with the Cu seed layer deposited on an Al sacrificial layer. If the sacrificial layer is a laser-cleavable polymer, any appropriate seed layer and interconnect post metallization may be used.

In some implementations, a solderable material can be plated in the photoresist pattern prior to plating the interconnect posts (not shown). Examples of solderable materials include Cu, Au, Sn, Pd, Ag, and combinations thereof including Au/Sn bilayers, Sn/Ag bilayers, Ni/Pd bilayers, Ni/Au bilayers, and Ni/Pd/Au trilayers.

FIG. 11D shows a cross-sectional illustration of the interconnect posts 1108 on the sacrificial layer 1104 after removal of the photoresist layer 1106. The photoresist layer 1106 can be stripped by a technique appropriate for the photoresist, with post-strip cleans of resist-related residue performed in some implementations.

FIG. 11E shows a cross-sectional illustration of a dielectric layer 1110 formed around the interconnect posts 1108. Because the dielectric material of the dielectric layer 1110 is flowable when dispensed or otherwise deposited, it can conformally surround the interconnect posts 1108. The dispensed flowable dielectric material covers and conforms to the topology of the underlying sacrificial layer 1104 and the interconnect posts 1108 without significant voids. For example, the flowable dielectric material may be deposited around the interconnect posts 1108, and in some cases, extend over the tops of the posts. Suitable flowable dielectric materials can include materials with a low dielectric constant, a low loss tangent, and a CTE similar to the CTE of the carrier substrate 1102. Examples of suitable flowable dielectric materials can include epoxies and spin-on dielectrics, such as spin-on glasses.

A spin-on dielectric refers to any solid dielectric deposited by a spin-on deposition process, which also may be referred to as a spin coating process. In a spin-on deposition process, a liquid solution containing dielectric precursors in a solvent is dispensed on the sacrificial layer 1104. The carrier substrate 1102 may be rotated while or after the solution is dispensed to facilitate uniform distribution of the liquid solution during rotation by centrifugal forces. Rotation speeds of up to about 6000 rpm may be used. Spin-on dielectrics can also include dielectrics formed by dispensing, extruding or casting a liquid solution without subsequent spinning. In some implementations, for example for large panel or continuous roll processes, the spin-on glass can be dispensed with an extrusion mechanism using a blade type nozzle, with no subsequent spinning. The dispensed solution can then be subjected to one or more post-dispensation operations to remove the solvent and form the solid dielectric layer. In some implementations, the dielectric precursor is polymerized during a post-dispensation operation. A spin-on dielectric layer can be an organic or inorganic dielectric layer according to the dielectric precursor used and the desired implementation. In some implementations, multiple layers can be dispensed and cured to build up the spin-on dielectric layer. In implementations where the interposer provides an electrical connection to a glass device substrate, it can be useful to use a dielectric that, once solidified, has a CTE that is matched with the CTE of the glass device substrate. Hence, in some implementations, the dielectric layer 1110 is a spin-on glass layer.

In some implementations, the dielectric layer 1110 can include an epoxy, such as a UV curable or thermally curable epoxy, that is flowable when dispensed. The epoxy can be a two-part epoxy with a resin and a hardener. In some implementations, the epoxy can have an epoxide resin and a polyamine hardener. For example, SU-8 from MicroChem in Newton, Mass. can be one such suitable epoxy.

A flowable dielectric material can be cured to solidify it, forming a solid dielectric layer. FIG. 11E shows the dielectric layer 1110 after solidification. In some implementations, the dielectric layer 1110 can be cured through a thermal anneal at a temperature of between about 100° C. and 450° C. In some implementations, a single dispensation operation can be performed to form the dielectric layer 1110. In some implementations, multiple dispensing/post-dispensing operation cycles can be performed to form the dielectric layer 1110. The dielectric layer 1110 can be dispensed to a thickness greater than the thickness of the interposer layer to accommodate shrinkage during anneal and subsequent planarization. In some implementations, after curing, the surface of a layer of the dielectric material 1110 can include bumps over the interconnect posts 1108, as illustrated in FIG. 11E. After curing, the solid dielectric material 1110 can form the substrate material of a through-substrate via interposer layer 1100.

FIG. 11F shows the interposer layer 1100 after planarization of the dielectric layer 1110 and the addition of an optional capping layer. The dielectric layer 1110 can be planarized such that surfaces of the interconnect posts 1108 are exposed and accessible for electrical connection. Planarizing the dielectric layer 1110 can include one or more operations, including lapping, grinding, chemical mechanical planarization (CMP), anisotropic dry etching, or another appropriate method. Furthermore, planarization of the dielectric layer 1110 can remove part of the interconnect posts 1108. In some implementations, planarization can remove between about 5% and about 25% of the interconnect posts 1108.

Also in some implementations, one or more passive components (not shown), such as capacitors, inductors and resistors, can be fabricated on the dielectric layer 1110 after planarization.

In some implementations as illustrated in FIG. 11F, the interconnect posts 1108 can be capped by plating a solderable material on the exposed surfaces of the interconnect posts 1108. The interconnect caps 1112 can include solderable metallurgies such as Cu, Au, Sn, Pd, Ag, and combinations thereof including Au/Sn bilayers, Sn/Ag bilayers, Ni/Pd bilayers, Ni/Au bilayers, and Ni/Pd/Au trilayers. In some implementations, the interconnect caps 1112 have a different metallization than that used for the sacrificial layer 1104. This is to preserve etch selectivity of the sacrificial layer 1104 with respect to the interconnect caps 1112. For example, a Ni/Pd/Au interconnect cap 1112 may be plated on a Ni or Ni alloy interconnect post 1108, with a Cu seed layer serving as the sacrificial layer 1104. In another example, a Cu or Ni/Pd/Au interconnect cap 1112 may be plated on a Cu or Ni alloy interconnect post 1108, with an Al layer serving as the sacrificial the layer 1104.

In some implementations, the thickness of the plated solderable metal can be between about 0.5 microns and about 2 microns. The interconnect caps 1112 can be used to protect the interconnect posts 1108 from oxidation. In addition, the interconnect caps 1112 can be used to provide an electrical connection between materials that could not otherwise be electrically connected. While the interconnect caps 1112 depicted in FIG. 11F cap the interconnect posts 1108 only on the top surface of the interposer layer 1100, in some other implementations, the interconnect posts 1108 can be capped on the bottom surface. For example, as described above with respect to FIG. 11C, a solderable material can be plated in the photoresist pattern prior to plating the interconnect posts 1108. The plated solderable material can serve to cap the interconnect posts in some implementations.

In some implementations, channels 1114 can be formed in the interposer layer 1100 by dicing the dielectric layer 1110. Dicing the dielectric layer 1110 can be achieved by, for example, mechanically sawing or laser cutting the dielectric layer 1110 to form the channels 1114. The channels 1114 can be spaced apart to form the eventual die sizes. In some implementations, the pitch of the channels 1114 can vary between about every 1 mm and about every 15 mm, with the die sizes also between about 1 mm and about 15 mm. In some implementations, the channels 1114 can provide an entry point for a wet etchant that is selective to the sacrificial layer 1104. The channels 1114 may be omitted in some implementations, for example, where the sacrificial layer 1104 is removed via laser ablation.

FIG. 11G shows the diced through-substrate via interposer layer 1100 after being released from the carrier substrate 1102. In some implementations, releasing the interposer layer 1100 from the carrier substrate 1102 can be achieved by etching the exposed sacrificial layer 1104 with an etchant that is selective to the sacrificial layer 1104. Selective etchants can include etchants that have a selectivity of at least about 100:1 or higher for the sacrificial layer 1104. Specific examples of etchants for selective etching of copper layers include a mixture of acetic acid (CH₃COOH) and hydrogen peroxide (H₂O₂), and ammoniacal-based etchant such as BTP copper etchant from Transene Company, Inc. in Danvers, Mass. Examples of etchants for selective etching of aluminum layers include sodium hydroxide (NaOH), potassium hydroxide (KOH), and alkaline solutions combined with an oxidizer. In some implementations, releasing the interposer layer 1100 from the carrier substrate 1102 can be achieved by laser ablation of the sacrificial layer 1104. The laser beam can ablate the sacrificial layer 1104 through a transparent carrier substrate 1102. The laser beam can have a selected wavelength sufficient to ablate the sacrificial layer 1104, which can be made of a laser-cleavable polymer. In some implementations, the released carrier substrate 1102 can be reused. In some implementations, the carrier substrate may be ground, etched, or otherwise removed.

In some implementations, the dielectric layer 1110 can be etched back such that interconnect posts 1108 protrude along the bottom surface of the dielectric layer 1110 (not shown). In some implementations, protruding interconnect posts 1108 can be formed without etching back the dielectric layer 1110, for example, by using a carrier substrate having topographical features.

The resulting interposer layer 1100 can be between about 10 and 100 microns thick according to various implementations. Thicker interposer layers can also be fabricated in some implementations. For example, an interposer layer of about 300 microns to 500 microns can be fabricated using a photoresist of about 400 microns to about 600 microns thick. In some implementations, if for example such thick photoresists are not available, thicker interposer layers can be fabricated using multiple cycles of lithography, plating, flowable dielectric deposition and planarization. These cycles can be performed sequentially to build up an interposer layer of desired thickness on a carrier substrate, or can be performed in parallel with the resulting interposer layers stacked to form an interposer layer of any thickness. Accordingly, single or multiple cycles can be used to fabricate interposer layers of about 10 microns to over 500 microns thick. In some implementations, thinner through-substrate via interposers can correspond to faster performance in integrated circuit systems, and to a thinner stack height when in a stacked configuration.

The interconnect posts 1108 in the interposer layer 1100 can made of any suitable electrically conductive material. As noted above, examples of interconnect post materials can include but are not limited to Ni, Ni alloy, and Cu. In some implementations, the interconnect posts 1108 can be made of Cu, which has a low resistivity.

Additionally, the interconnect posts 1108 can have any appropriate size and shape. In some implementations, the height to width aspect ratio of the interconnect posts 1108 can be greater than about 5:1. For example, the interconnect posts 1108 can have a diameter between about 5 microns and about 100 microns. The height of the interconnect posts 1108 can be between about 10 microns and 500 microns, for example between about 25 microns and 100 microns. The interconnect posts 1108 can also be configured according to various shapes, such as circular, square, octagonal, hexagonal, and rectangular.

In some implementations, fabrication of an interposer may be complete at this stage, with the interposer including the interposer layer 1100 having through-substrate interconnects posts 1108 as well as other components, if any, formed on the solidified dielectric layer 1110 and/or on the interconnect posts 1108 such as the interconnect caps 1112 or passive components (not shown). In some other implementations, an interposer may further include one or more additional layers, such as routing or redistribution layers.

FIGS. 12A-12C show examples of cross-sectional schematic illustrations of varying implementations of interposers with one or more routing layers. A through-substrate via interposer 1200 can have routing layers 1216 on either or both sides of a through-substrate via interposer layer 1210. The through-substrate via interposer layer 1210 can be manufactured by any of the methods described above. A routing layer 1216, otherwise referred to as a redistribution layer (RDL), can include a plurality of electrically conductive routing lines 1212 and RDL contacts 1214 embedded in a dielectric material for carrying electrical signals. RDL pads 1218 can be disposed on the routing layer 1216 to provide a point of external electrical connection. In some implementations, the routing layer 1216 can serve as an electrical interconnect between the contact points of interconnect posts 1208 in the through-substrate via interposer layer 1210 and various dies (not shown) through routing lines 1212, RDL contacts 1214, and RDL pads 1218. Although FIGS. 12A-12C show only one routing layer 1216 on the top and/or bottom side of the through-substrate via interposer layer 1210, in some implementations, there can be more than one routing layer 1216 on each side.

Each routing layer 1216 can be formed by a series of process steps including deposition of dielectric material and conductive lines, photolithography, etching, and planarization. The dielectric material in a routing layer 1216 can be a solidified flowable dielectric material as described above or can be another dielectric material. Examples of dielectric materials include a polyimide material, a benzocyclobutene material, a polybenzoxazole material, and an ABF film available from Ajinomoto Fine-Techno. In one example, the routing lines 1212 can be about 10 microns thick, and dielectric thickness in the routing layer 1216 can be about 15 microns to 25 microns thick.

The interconnect posts 1208 and other electrical components such as the routing lines 1212, the RDL contacts 1214, and the RDL pads 1218, can be defined according to density. In some implementations, the density of one or more of the routing lines 1212, the RDL contacts 1214 and the RDL pads 1218 can be greater than the density of the interconnect posts 1208. Alternatively, the interconnect posts 1208, the routing lines 1212, the RDL contacts 1214, and the RDL pads 1218 can be defined according to pitch, where pitch defines the center-to-center spacing between electrically conductive components. In some implementations, the pitch at the top surface of the interposer 1200 can be greater than the pitch at the bottom surface of the interposer 1200. For example, the pitch of the interconnect posts 1208 can be greater than the pitch of the RDL pads 1218. In some implementations, the pitch at the top surface of the interposer 1200 can be between about 20 microns and 125 microns and the pitch at the bottom surface of the interposer 1200 can be between about 100 microns and 500 microns.

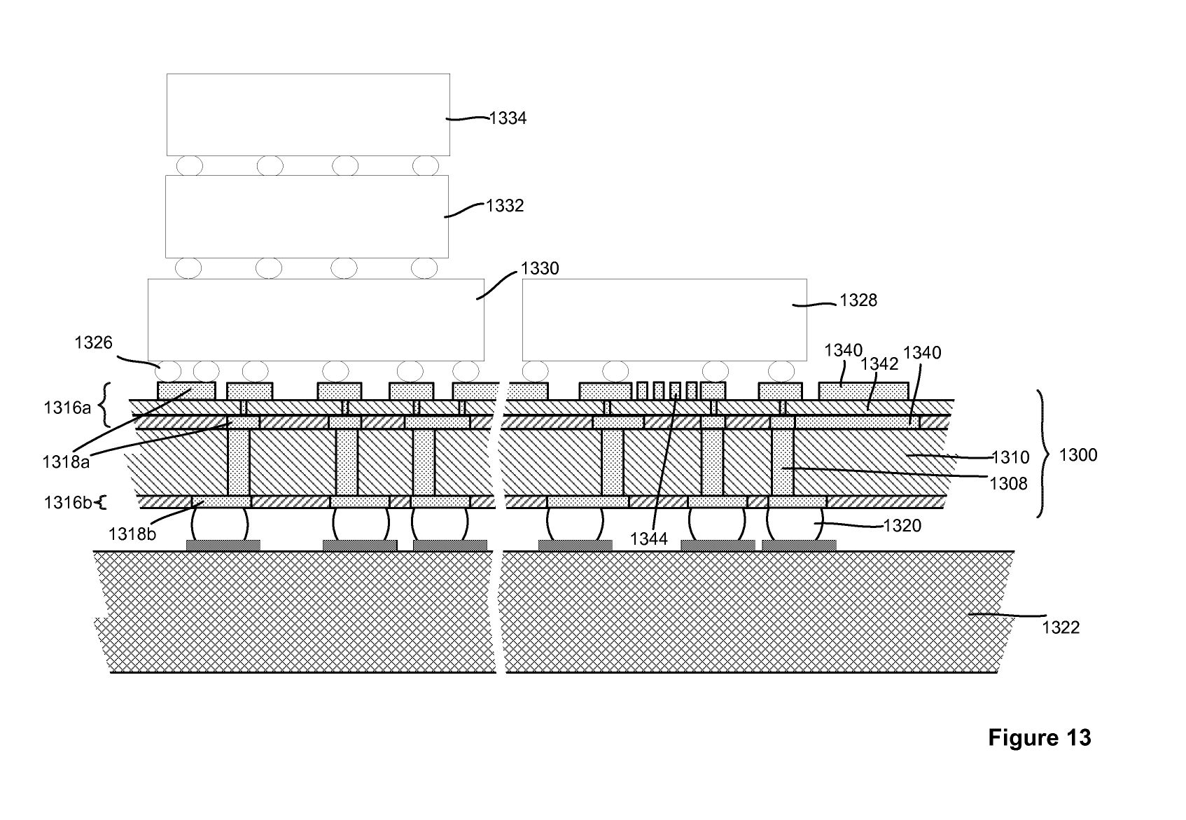

In some implementations, the routing layer 1216 can include passive components (not shown). For example, passive components such as capacitors, resistors, and/or inductors can be coupled with the routing lines 1212 in the routing layer 1216 to provide regulated power between the interconnect posts 1208 and the various dies. Examples of passive components in a routing layer are described below with respect to FIG. 13.

FIG. 12A shows a cross-sectional illustration of an interposer 1200 including a routing layer 1216 and a through-substrate via interposer layer 1210, with the routing layer 1216 disposed on the top surface of the through-substrate via interposer layer 1210. In some implementations, the routing layer 1216 may be manufactured after planarization of the dielectric material of the through-substrate via interposer layer 1210. For example, a routing layer may be formed on the top surface of the interposer layer 1100 shown in FIG. 11F or FIG. 11G, or after block 908 of FIG. 9. The routing layer 1216 may include passive components that electrically connect to the interconnect posts 1208.

FIG. 12B shows a cross-sectional illustration of an interposer 1200 including a routing layer 1216 and a through-substrate via interposer layer 1210, with the routing layer 1216 disposed on the bottom surface of the through-substrate via interposer layer 1210. In some implementations, the routing layer 1216 may be manufactured after forming the sacrificial layer on the carrier substrate but before applying any patterned photoresist layer. For example, a routing layer may be formed on the sacrificial layer 1104 in FIG. 11A or after block 902 in FIG. 9. In some implementations, the routing layer 1216 may be manufactured after release of a carrier substrate. For example, a routing layer may be formed on the bottom surface of the dielectric layer 1110 in FIG. 11G. The routing layer 1216 may include passive components that electrically connect to the interconnect posts 1208.

FIG. 12C shows a cross-sectional illustration of an interposer 1200 with routing layers 1216a and 1216b on both the top and bottom surface of a through-substrate via interposer layer 1200. In some implementations, the routing layer 1216b may be manufactured after forming the sacrificial layer on the carrier substrate but before applying any patterned photoresist. In some implementations, one or both of the routing layers 1216a and 1216b may be manufactured after planarization of the dielectric material. The routing layers 1216a and 1216b can include passive components that electrically connect to the interconnect posts 1208.

The interposers described herein may be applied with various components in 3-D electronics packaging depending on the application. In some implementations, the interposer may be implemented in one or more application specific integrated circuits (ASICs), digital signal processors (DSPs), digital signal processing devices (DSPDs), programmable logic devices (PLDs), field programmable gate arrays (FPGAs), memory stacks, processors, controllers, microcontrollers, and other electronic devices. One example of an interposer as implemented in a 3-D device package is depicted in FIG. 13, described below.

FIG. 13 shows an example of a cross-sectional schematic illustration of stacked dies on an interposer according to one implementation. The packaging system includes a packaging substrate 1322, which can be a material that provides base mechanical support to the 3-D device package. In some implementations, the packaging substrate 1322 can be a metal, semiconductor, ceramic, plastic, glass, or a ceramic, organic or fiberglass printed circuit board (PCB) material.

In FIG. 13, the packaging system can include electrical connectors 1320 positioned over a packaging substrate 1322. In some implementations, the electrical connectors 1320 can include under bump metallization (UBM) or solder balls in contact with the packaging substrate 1322. In some implementations, the electrical connectors 1320 may be positioned under the packaging substrate 1322. The electrical connectors 1320 can serve to electrically and physically couple components within the packaging system and can be made of electrically conductive material. As illustrated in FIG. 13, the electrical connectors 1320 can connect an interposer 1300 with the packaging substrate 1322 so that the interposer 1300 is in electrical communication with the packaging substrate 1322.

The interposer 1300, such as one manufactured by any of the methods described earlier herein, can include a solidified dielectric material 1310 and one or more metal interconnect posts 1308 extending through the solidified dielectric material 1310. In some implementations, the solidified dielectric material 1310 includes spin-on glass or epoxy material. The interposer 1300 can further include routing layers 1316a and 1316b with electrically conductive routing lines 1318a and 1318b connected to the one or more metal interconnect posts 1308. In some implementations, the interposer layer 1300 can include one or more passive components such as one or more inductors, capacitors, or resistors. For example, the passive components can include an inductor electrically coupled to the routing lines 1318 to regulate electrical flow. In FIG. 13, the routing layer 1316a includes a metal-insulator-metal capacitor formed by insulator layer 1342 and metal layers 1340 and a spiral inductor 1344. The conductive and insulator materials used to form passive components can be the same or different materials used to form the routing lines and main dielectric material of a routing layer.

The routing layer 1316a is a multi-layer redistribution network including alternating layers of metallization and dielectric material. In some implementations, forming the routing layer 1316a includes forming alternate layers of plated metal, such as plated Cu, and dielectric film. The uppermost layer can include UBM (not shown) for attaching dies.

The packaging system can further include electrical connectors 1326 to connect the interposer 1300 with dies 1328, 1330, 1332, and 1334 positioned over the interposer 1300. The electrical connectors 1326 can be any appropriate electrically conductive material such as solder balls. In some implementations, the density of the electrical connectors 1326 from the routing layer 1316 of the interposer 1300 to the dies 1328, 1330, 1332, and 1334 can be greater than the density of the electrical connectors 1320 from the packaging substrate 1322 to the interposer 1300. In some implementations, two or more of the dies 1328, 1330, 1332, and 1334 can be stacked or mounted over one another. In some implementations, the dies 1328, 1330, 1332, and 1334 can include one of a memory, logic, or MEMS chip. It is understood that any number of dies may be mounted in various configurations over the interposer 1300 to achieve a desired implementation. In some implementations, an interposer can have a CTE between the CTE's of the dies, substrates, or layers that it connects. For example, in some implementations, an overlying silicon die may have a CTE of about 3 parts per million (ppm) and an underlying PCB may have a CTE of about 16 ppm; an interposer layer disposed between the silicon die and the PCB may have a CTE between about 3 ppm and 16 ppm, for example, between about 5 and 14 ppm.

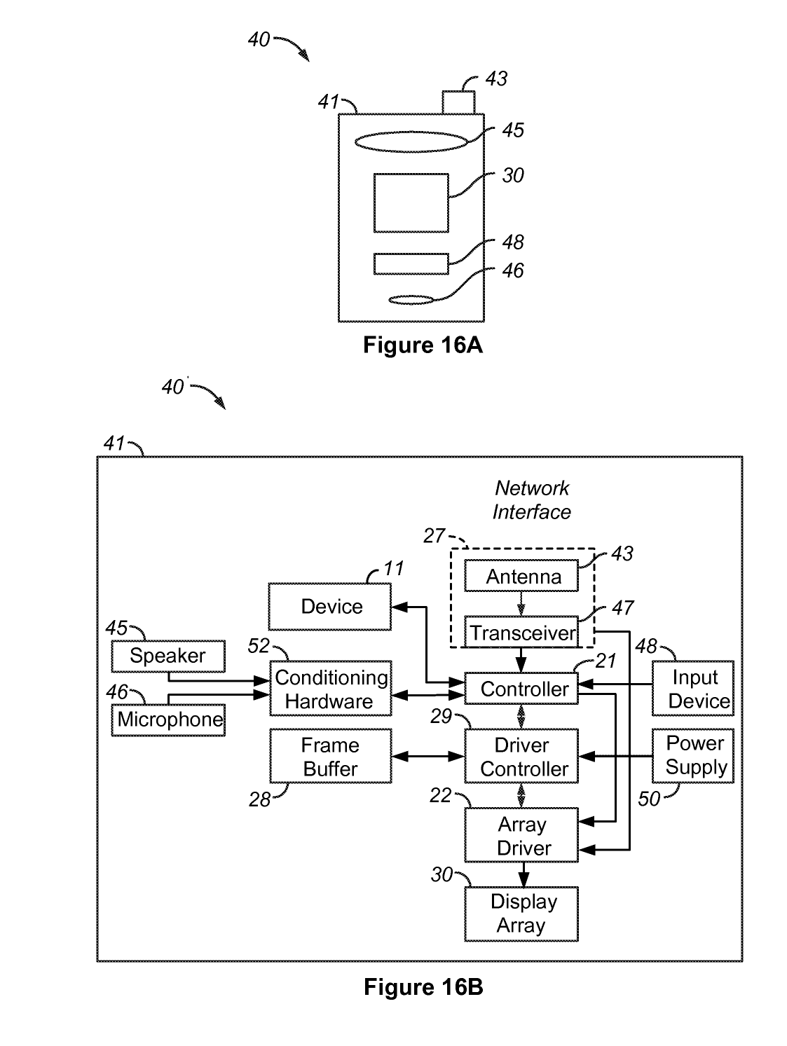

In some implementations, an interposer can be used as part of a 3-D or other package including a display or non-display device fabricated on a glass or epoxy substrate, the combination having well-matched thermal expansion properties. In some implementations, the interposer can be used to communicate data to a processor (such as processor 21 of FIG. 16B).

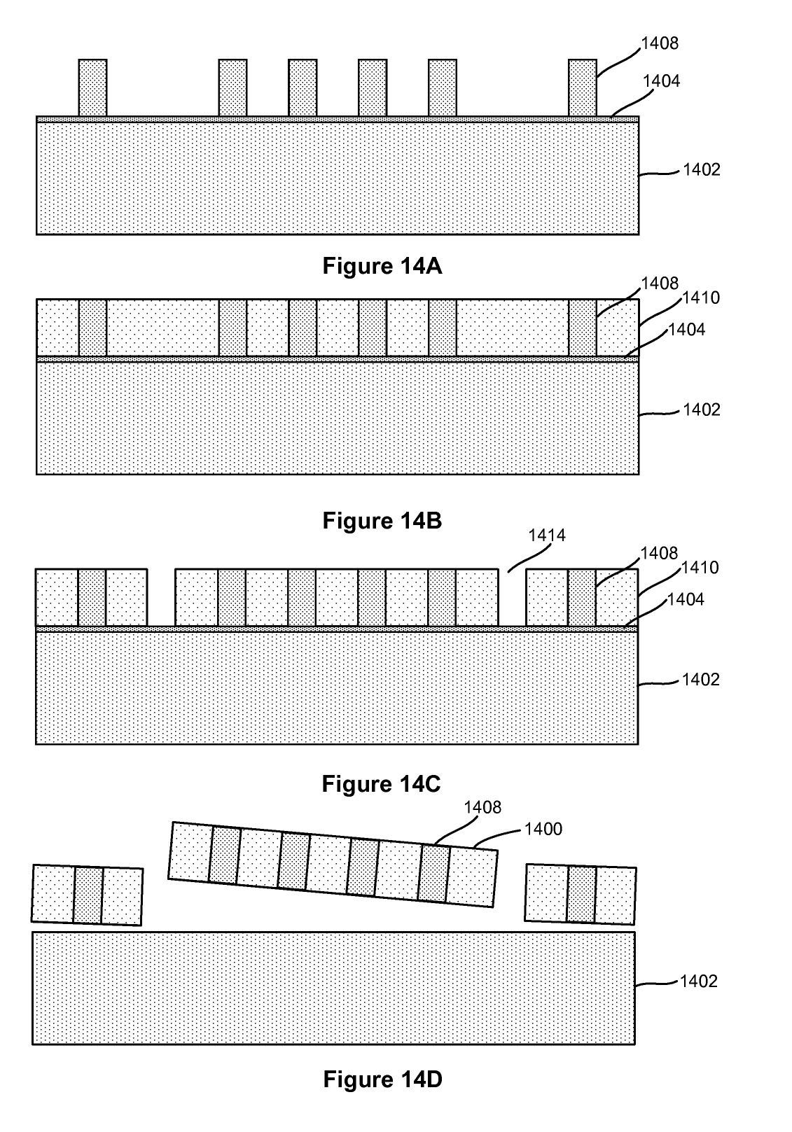

FIGS. 14A-14D show examples of cross-sectional schematic illustrations of various stages in a method of forming an interposer. The interposer 1400 is formed in a sequence of stages including forming a plurality of interconnect posts 1408 on a sacrificial layer 1404 that has been deposited on a carrier substrate 1402 such as a glass substrate or panel, as shown in FIG. 14A. The sacrificial layer 1404 may also serve as a seed layer for subsequent electro- or electroless plating. An additional seed layer (not shown) may be deposited on the sacrificial layer 1404 prior to plating the interconnect posts. The interconnect posts 1408 may be formed by spinning, dispensing, or otherwise depositing a photoresist layer (not shown) on the sacrificial layer 1404; exposing and developing the photoresist layer to form holes for the interconnect posts 1408; and plating the interconnect posts 1408 through the patterned photoresist. The photoresist layer is subsequently removed. As shown in FIG. 14B, one or more flowable dielectric layers 1410 may be spun, dispensed, cast, or otherwise deposited around and possibly over the interconnect posts 1408 on the sacrificial layer 1404. The dielectric layer 1410 is solidified and may be planarized to expose the interconnect posts 1408. As shown in FIG. 14C, dicing streets 1414 may be cut through the dielectric layer 1410 to expose at least a portion of the sacrificial layer 1404. The cuts may extend into or through the carrier substrate 1402. As shown in FIG. 14D, a sacrificial layer etchant may be used to remove the sacrificial layer 1404 and release the interposer 1400, including interconnect posts 1408, from the carrier substrate 1402.

One or more routing layers (not shown) may be formed on an upper side, lower side, or both sides of the interposer 1400 prior to depositing the flowable dielectric layer 1410 or after the planarization of the dielectric layer 1410, as described above with respect to FIGS. 12A-12C. One or more passive components (not shown) such as a resistor, a capacitor, an inductor, a coupling transformer, or a power combiner may be formed on an upper side or a lower side of the interposer 1400, as described above with respect to FIG. 10 and FIG. 13.

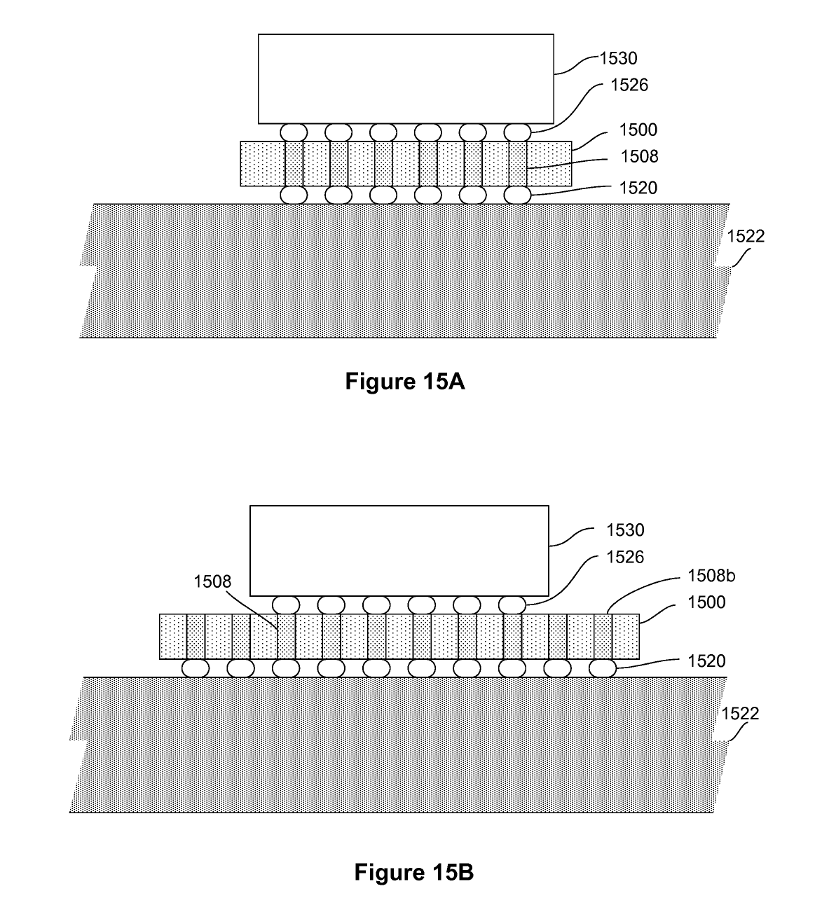

FIGS. 15A and 15B show examples of cross-sectional schematic illustrations of an interposer positioned between an integrated circuit chip and a packaging substrate. In FIG. 15A, an interposer 1500 with a plurality of interconnect posts 1508 is connected between a packaging substrate 1522, such as a PCB, and an integrated circuit chip 1530, also referred to as a die that may be a memory chip, a logic device, a radio frequency (RF) chip, an ASIC, a MEMS chip, or other electronic or mechanical device. Solder bumps or balls 1520 may be used to attach the interposer 1500 to the packaging substrate 1522. Similarly, solder bumps or balls 1526 may be used to attach integrated circuit chip 1530 to corresponding interconnect posts 1508 on interposer 1500. Additional dies (not shown) may be stacked on top of integrated circuit chip 1530, or positioned laterally to integrated circuit chip 1530 and connected to other interconnect posts 1508.

The interposer 1500 may provide stress isolation and strain relief when the interposer 1500 is connected between the packaging substrate 1522 and the integrated circuit chip 1530. Strain relief may be provided, for example, when the temperature of the integrated circuit chip 1530 rises substantially with respect to the packaging substrate 1522. Alternatively, strain relief may be provided when the overall temperature of integrated circuit chip 1530, interposer 1500, and packaging substrate 1522 rise and stress is generated due to differences in the CTE between the integrated circuit chip 1530 and the packaging substrate 1522. Extra interconnect posts 1508b, as shown in FIG. 15B, may be provided to enhance the strain relief due to CTE mismatches. The extra interconnect posts 1508b may be attached only to the packaging substrate 1522 as shown, attached only to the integrated circuit die 1530 (not shown), or attached to both the integrated circuit die 1530 and the packaging substrate 1522. Extra bond pads may be provided on the integrated circuit chip 1530 or the packaging substrate 1522 that are dedicated to strain relief.

Alternatively or in addition to providing electrical connections and possible strain relief between the integrated circuit chip 1530 and the packaging substrate 1522, one or more interconnect posts 1508 may be positioned to provide increased heat transfer between the integrated circuit chip 1530 and the packaging substrate 1522, so that the integrated circuit chip 130 may be kept at a lower temperature closer to that of the packaging substrate 1522 during operation.

An underfill material (not shown) such as an epoxy may be positioned between the interposer 1500 and the underlying packaging substrate 1522. The underfill material may be injected, for example, between the interposer 1500 and the packaging substrate 1522 and then cured. The underfill material may provide additional stress isolation and protection from excessive shearing forces that may develop during high temperature excursions. The underfill material may also provide additional heat transfer capability between the interposer 1500 and the packaging substrate 1522. Similarly, underfill material may be positioned between the interposer 1500 and an attached integrated circuit chip 1530. Molding compound (not shown) customary in many packaging configurations may be placed over the integrated circuit chip 1530, the interposer 1500, and portions of the packaging substrate 1522.

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of forming an interposer comprising:
forming a sacrificial layer on a carrier substrate;
forming a plurality of interconnect posts on the sacrificial layer, the interconnect posts oriented substantially perpendicularly to the carrier substrate;
depositing and solidifying one or more flowable dielectric layers to cover the sacrificial layer and the plurality of interconnect posts with a dielectric material; and
planarizing the solidified dielectric material to expose the plurality of interconnect posts and to form an interposer layer releasably attached to the carrier substrate via the sacrificial layer.

2. The method of claim 1, wherein the one or more flowable dielectric layers include one or more spin-on dielectric layers.

3. The method of claim 1, wherein the one or more flowable dielectric layers include one or more epoxy layers.

4. The method of claim 1, wherein forming a plurality of interconnect posts includes plating a plurality of metal posts in a patterned photoresist layer.

5. The method of claim 1, further comprising forming one or one more passive components on the solidified dielectric material.

6. The method of claim 5, wherein forming the one or more passive components is performed after planarizing the solidified dielectric material.

7. The method of claim 5, wherein forming the one or more passive components is performed after forming the sacrificial layer on the carrier substrate but before depositing any flowable dielectric layers.

8. The method of claim 1, further comprising forming one or more routing layers on the solidified dielectric material.

9. The method of claim 1, further comprising plating the plurality of interconnect posts with solderable material.

10. An interposer comprising:
an additive glass interposer layer; and
one or more metal interconnect posts extending through the glass interposer layer.

11. The interposer of claim 10, further comprising one or more passive components on the glass interposer layer.

12. The interposer of claim 11, wherein the one or more passive components include at least one of a resistor, a capacitor, and an inductor.

13. The interposer of claim 10, wherein the one or more metal interconnect posts include at least one of nickel, a nickel alloy, and copper.

14. The interposer of claim 10, wherein the one or more metal interconnect posts have a height to width aspect ratio of greater than about 5:1.

15. The interposer of claim 10, wherein the one or more metal interconnect posts have a height of from about 10 microns to about 500 microns and a width of from about 5 microns to about 100 microns.

16. The interposer of claim 10, wherein the glass interposer layer has a thickness between about 10 and 500 microns.

17. The interposer of claim 10, wherein the one or more interconnect posts include an interconnect cap that protrudes from the glass interposer layer.

18. The interposer of claim 17, wherein the interconnect cap includes a solderable material.

19. The interposer of claim 10, further comprising a routing layer including electrically conductive routing lines connected to the one or more metal interconnect posts.

20. The interposer of claim 19, wherein the density of the routing lines is greater than the density of the metal interconnect posts.

21. A method of forming an interposer, comprising:
using an additive process to fabricate an additive glass interposer layer on a carrier substrate; and
integrating one or more passive components within the interposer layer during the additive process.

22. The method of claim 21, wherein the one or more passive components include at least one of a resistor, a capacitor and an inductor.

23. The method of claim 21, wherein using the additive process includes depositing flowable dielectric material around a plurality of metal interconnect posts and the carrier substrate after forming the plurality of metal interconnect posts on the carrier substrate.

24. An apparatus, comprising:
a packaging substrate;
an interposer layer in electrical communication with the packaging substrate, wherein the interposer layer includes:
a solidified dielectric material;
one or more metal interconnect posts extending through the solidified dielectric material;
a routing layer including electrically conductive routing lines connected to the one or more metal interconnect posts; and
one or more dies positioned over the interposer layer, wherein the density of electrical connections from the routing layer to the one or more dies is greater than the density of electrical connections from the interposer layer to the packaging substrate.

25. The apparatus of claim 24, wherein the one or more dies include at least one of memory, logic, radio frequency (RF), ASIC or MEMS chips.

26. The apparatus of claim 24, wherein the one or more dies includes a plurality of stacked dies.

27. The apparatus of claim 24, further comprising one or more passive components within the interposer layer.

28. The apparatus of claim 24, wherein the solidified dielectric material includes spin-on-glass or epoxy.

29. The apparatus of claim 24, further comprising:
a display;
a processor that is configured to communicate with the display, the processor being configured to process image data; and
a memory device that is configured to communicate with the processor.

30. The apparatus of claim 29, further comprising:
a driver circuit configured to send at least one signal to the display; and
a controller configured to send at least a portion of the image data to the driver circuit.

31. The apparatus of claim 29, further comprising:
an image source module configured to send the image data to the processor.

32. The apparatus of claim 31, wherein the image source module includes at least one of a receiver, transceiver, and transmitter.

33. The apparatus of claim 29, further comprising:
an input device configured to receive input data and to communicate the input data to the processor.

34. An apparatus, comprising:
an interposer, wherein the interposer is formed by forming a plurality of interconnect posts on a sacrificial layer, the sacrificial layer formed on a carrier substrate; depositing and solidifying one or more flowable dielectric layers around the interconnect posts; planarizing the solidified dielectric material to expose the interconnect posts; and releasing the interposer from the carrier substrate by sacrificially etching the sacrificial layer.

35. The apparatus of claim 34, wherein at least one interconnect post provides strain relief when the interposer is connected between a packaging substrate and an integrated circuit chip.

36. The apparatus of claim 34, wherein at least one interconnect post allows heat transfer between an integrated circuit chip and a packaging substrate, the interposer connected between the packaging substrate and the integrated circuit chip.

37. The apparatus of claim 34, further comprising one or more routing layers on an upper side or a lower side of the interposer.

38. The apparatus of claim 34, further comprising at least one passive component formed on an upper side or a lower side of the interposer.

39. The apparatus of claim 34, further comprising at least one integrated circuit chip attached to the interposer.

40. The apparatus of claim 34, further comprising a packaging substrate attached to the interposer.

41. The apparatus of claim 34, wherein the packaging substrate is a printed circuit board.

42. The apparatus of claim 34, wherein the interposer provides stress isolation between the packaging substrate and an integrated circuit chip attached to the interposer.
